(19) United States
(12) Patent Application Publication
(10) Pub. No.: US 2009/0053439 A1
(43) Pub. Date: Feb. 26, 2009

(54) FILM TYPE ANTENNA, CASE STRUCTURE, AND METHOD OF MANUFACTURING THE SAME

(75) Inventors: Jae Suk SUNG, Yongin (KR); Jang Ho Park, Suwon (KR); Young Suk Kim, Suwon (KR); Dae Seong Jeon, Suwon (KR); Kyongkeun Lee, Suwon (KR); Ha Ryong Hong, Hwasung (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/196,108

(22) Filed: Aug. 21, 2008

(30) Foreign Application Priority Data
Aug. 22, 2007 (KR) 10-2007-0084430

(51) Int. Cl. H01Q 1/42; B32B 15/08; B32B 3/10; B29C 65/70; B44C 1/22; C23C 14/34

(52) U.S. Cl. 428/35.7; 428/195.1; 428/201; 156/278; 156/256; 264/259; 216/41; 204/192.35; 343/872

(57) ABSTRACT

There are provided a film type antenna, a case structure using the same, and a method of manufacturing the same. A film type antenna according to aspect of the invention may include: a first polymer film; a decorative layer provided on one surface of the first polymer film; a second polymer film stacked on the decorative layer and having one surface in contact with the decorative layer; and an antenna pattern provided on the other surface of the second polymer film.

### CROSS-REFERENCE TO RELATED APPLICATIONS

This application claims the priority of Korean Patent Application No. 2007-84430 filed on Aug. 22, 2007, in the Korean Intellectual Property Office, the disclosure of which is incorporated herein by reference.

### BACKGROUND OF THE INVENTION

1. Field of the Invention

The present invention relates to film type antennas, case structures using the same, and more particularly, to a film type antenna having an antenna pattern and a decorative layer integrally formed with each other, and a case structure having a housing to which the film type antenna is attached.

2. Description of the Related Art

Recently, mobile communication terminals, such as GPS, PDAs, cellular phones, and wireless notebook computers, have come into widespread use. A reduction in size, thickness, and weight has been increasingly required for the mobile communication terminals. In order to meet these needs, emphasis is placed upon reducing volume of the mobile communication terminals, and at the same time, the mobile communication terminals need to maintain various functions. Particular attention is also placed upon antennas, which are one of the most important components of mobile communication terminals.

In general, among antennas of mobile communication terminals, an external antenna, such as a rod antenna or a helical antenna, protrudes from the outside of a mobile communication terminal by a predetermined distance. This prevents a reduction in size and portability of the terminal. Further, if the terminal falls down, the external antenna becomes susceptible to damage.

On the contrary, an internal antenna that is mounted onto the inside of the mobile communication terminal may be less damaged. However, the physical size of the internal antenna makes it difficult to reduce the size of the mobile communication terminal.

Further, when the outside of a case of the mobile communication terminal is decorated with a character and a pattern, the character or pattern is printed by using a spraying method or a coating method. However, in this case, the character for decoration may be susceptible to damage by the external impact of the terminal or by physical friction.

### SUMMARY OF THE INVENTION

An aspect of the present invention provides a film type antenna having an antenna pattern and a decoration layer formed integrally with each other and a case structure having the film type antenna attached thereto.

According to an aspect of the present invention, there is provided a film type antenna including: a first polymer film; a decorative layer provided on one surface of the first polymer film; a second polymer film stacked on the decorative layer and having one surface in contact with the decorative layer; and an antenna pattern provided on the other surface of the second polymer film.

The first and second polymer films may be formed of the same material.

The decorative layer may be a film having a predetermined pattern printed thereon.

According to another aspect of the present invention, there is provided a case structure including: a housing having at least one surface to which a film type antenna is provided, wherein the film type antenna includes: a first polymer film; a decorative layer provided on one surface of the first polymer film; a second polymer film stacked on the decorative layer and having one surface in contact with the decorative layer; and an antenna pattern provided on the other surface of the second polymer film.

The case structure may be a case of a mobile communication terminal.

The film type antenna may have the antenna pattern in contact with a surface of the housing.

The film type antenna may be provided on an outer surface of the housing.

According to still another aspect of the present invention, there is provided a method of manufacturing a film type antenna, the method including: forming a decorative layer on one surface of a first polymer film; stacking a second polymer film so that one surface of the second polymer film is in contact with the decorative layer; and forming an antenna pattern on the other surface of the second polymer film.

The first polymer film and the second polymer film may be formed of the same material.

The forming a decorative layer may include stacking a film having a predetermined pattern printed thereon on the first polymer film.

The forming an antenna pattern may include: forming metal foil on the second polymer film; forming a resist layer having the shape of an antenna on the metal foil; etching an exposed area of the metal foil; and removing the resist layer.

The forming an antenna pattern may include: attaching a masking tape perforated in the shape of a desired antenna; sputtering metal used to form an antenna on the surface of the second polymer film to which the masking tape is attached; and removing the masking tape from the second polymer film.

The forming an antenna pattern may include: cutting the metal foil to a desired shape; and attaching the cut metal foil to the second polymer film.

According to yet another aspect of the present invention, there is provided a method of manufacturing a case structure, the method including: forming a film type antenna in which a first polymer film, a decorative layer, a second polymer film, and an antenna pattern are sequentially stacked; inserting the film type antenna into a mold having the shape of a case structure; and forming a housing by inserting a molding material into the mold.

The case structure may be a case of a mobile communication terminal.

In the inserting the film type antenna into the mold, the film type antenna may be disposed so that the antenna pattern is in contact with a surface of the housing.

In the inserting the film type antenna into a mold, the film type antenna may be disposed in contact with an outer surface of the housing.

The method of manufacturing a case structure may further include pre-forming the film type antenna to the shape of a desired case structure before inserting the film type antenna into the mold.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a cross-sectional view illustrating a film type antenna according to an exemplary embodiment of the invention;

FIG. 1B is an exploded perspective view illustrating the film type antenna of FIG. 1B;

FIG. 2 is a cross-sectional view illustrating a case structure according to another exemplary embodiment of the invention;

FIGS. 3A to 3C are procedural cross-sectional views illustrating a process of manufacturing the film type antenna of FIGS. 1A and 1B according to still another exemplary embodiment of the invention;

FIGS. 4A to 4D are procedural cross-sectional views illustrating a lithography process, which is one of the processes of forming an antenna pattern in FIG. 3; and

FIGS. 5A to 5D are procedural cross-sectional views illustrating a process of manufacturing a case structure according to yet another embodiment of the invention.

### DETAILED DESCRIPTION OF THE PREFERRED EMBODIMENT

Exemplary embodiments of the present invention will now be described in detail with reference to the accompanying drawings.

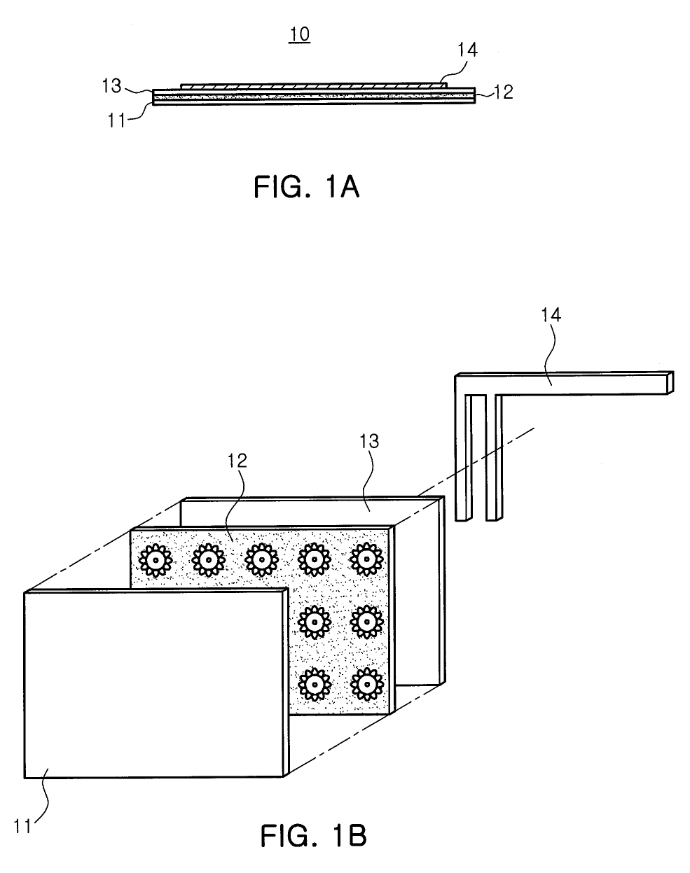

FIG. 1A is a cross-sectional view illustrating a film type antenna according to an exemplary embodiment of the invention. FIG. 1B is an exploded perspective view illustrating the film type of FIG. 1A.

Referring to FIGS. 1A and 1B, a film type antenna 10 may include a first polymer film 11, a decorative layer 12, a second polymer film 13, and an antenna pattern 14.

The film type antenna 10 may be attached to the surface of a housing by using an in-mold process. The first polymer film 11 may be formed of a material that does not undergo significant deformation by temperature and pressure during the molding process and at the same time, can be formed integrally with a case structure. Preferably, a polycarbonate (PC) and polyethylene terephthalate (PET) may be used.

Further, in this embodiment, when the film type antenna is attached to the case structure, the first polymer film 11 may be formed of a transparent material so that the decorative layer can be seen from the outside.

A decorative layer 12 may be formed on the first polymer film 11. The decorative layer 12 may be formed by printing a character or a pattern for decoration. Here, various characters or patterns may be used for decoration. In addition to the character and the pattern, numbers, company logs, and the like may be used for the decorative layer 12. As for the decorative layer 12, a pattern or the like may be directly printed on the first polymer film 11. In this embodiment, the film having a pattern printed thereon may be used.

The second polymer film 13 may be formed on the decorative layer 12. The second polymer film 13 may be formed of the same material as the first polymer film 11.

In this embodiment, the second polymer film 13 may completely cover the decorative layer 12.

The antenna pattern 14 may be formed on the second polymer film 13. The antenna pattern 14 may be a conductive pattern that is formed into various shapes. In this embodiment, the antenna pattern 14 may be implemented as an inverse F-type antenna pattern.

In the film type antenna 10 according to this embodiment, the first polymer film 11, the decorative layer 12, the second polymer film 13, and the antenna pattern 14 are sequentially stacked. The film type antenna 10 may have a thickness of approximately 0.1 to 0.4 mm so that the film type antenna can be attached to the surface of the case structure by an in-mold process.

An in-mold process may be used as a method of attaching the film type antenna like this embodiment to the outer surface of the housing. When the housing is formed by the in-mold process, if the film type antenna 10 having the first polymer film 11, the decorative layer 12, the second polymer film 13, and the antenna pattern 14 sequentially stacked to form a single body, is used, the antenna pattern or the decorative layer can be prevented from moving during the molding process, thereby ensuring safety during process.

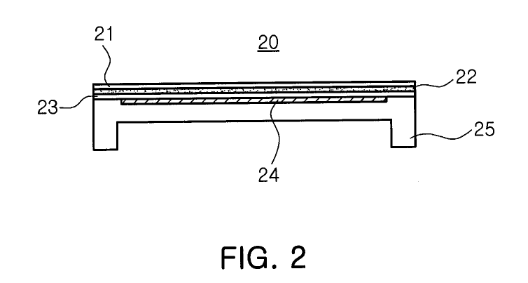

FIG. 2 is a cross-sectional view illustrating a case structure to which a film type antenna according to another exemplary embodiment of the invention is attached.

Referring to FIG. 2, a film type antenna may be attached to a case structure 20 according to this embodiment. In the film type antenna, a first polymer film 21, a decorative layer 22, a second polymer film 23, and an antenna pattern 24 may be sequentially attached to the surface of a housing 25.

In this embodiment, the film type antenna may be attached to an outer surface of the housing 25. Further, the first polymer film 21 may be exposed to the outside. The housing 25 may be a case of a mobile communication terminal.

According to this embodiment, a case structure can be obtained in which an antenna is integrally formed with the case of the mobile communication terminal, and the decorative layer is exposed on the outside of the housing to thereby obtain decorative effects of the mobile communication terminal. Further, the first polymer film 21 provides protection of the decorative layer 22 and the antenna pattern 24 against external impact or physical friction.

In FIG. 2, it is shown that the film-type antenna is attached to the housing 25. The first polymer film 21, the decorative layer 22, the second polymer film 23, and the antenna pattern 24 actually have a much smaller thickness than the housing 25.

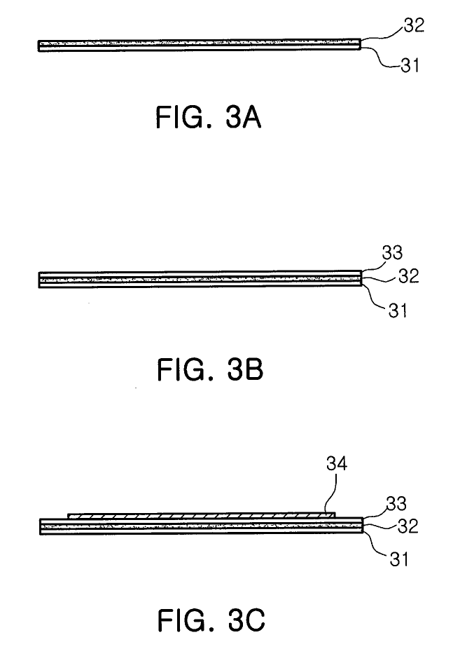

FIGS. 3A to 3C are procedural cross-sectional views illustrating a process of manufacturing a film type antenna according to still another exemplary embodiment of the invention.

In FIG. 3A, a decorative layer 32 is formed on a first polymer film 31.

The first polymer film 31 may be formed of a material that does not undergo significant deformation by temperature and pressure during the molding process and at the same time, can be formed integrally with a case structure. Preferably, a polycarbonate (PC), a polyethylene Terephthalate (PET) may be used.

The decorative layer 32 may be formed by a printing process. A predetermined character or pattern may be printed to form the decorative layer 32. The decorative layer 32 may be formed by directly printing a character or pattern on the first polymer film 31. Alternatively, the decorative layer 32 may be formed by attaching a separate film having a character printed thereon to the first polymer film 31. Therefore, the decorative layer 32 may be formed on a partial or entire area of one surface of the first polymer film 31.

In this embodiment, the film 32 having a pattern printed thereon is attached to the first polymer film 31.

In FIG. 3B, a second polymer film 33 is formed to cover the decorative layer 32.

The second polymer film 33 may be the same material as the first polymer film 31.

In order to improve adhesion between the second polymer film 33 and the decorative layer 32, an adhesive material may be added between the second polymer film 33 and the decorative layer 32 before attaching the second polymer film 33.

When the decorative layer 32 is formed at a partial area of one surface of the first polymer film 31, the first polymer film 31 and the second polymer film 32 may be in direct contact with each other. In this case, an adhesive may be added in order to improve the adhesion.

In FIG. 3C, an antenna pattern 34 is formed on the second polymer film 33.

The antenna pattern 34 may be formed by using various methods. For example, metal foil may be cut into a desired antenna pattern, and the cut metal foil may be attached to the second polymer film. Alternatively, a sputtering process may be directly performed on the second polymer film, or a printing process may be performed using a conductive ink to form the antenna pattern 34. Furthermore, the antenna pattern 34 may be formed by using a lithography process.

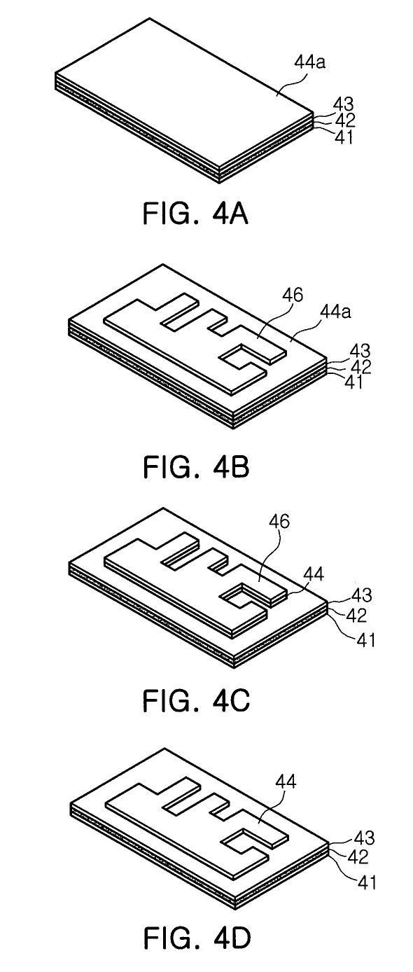

FIGS. 4A to 4D are cross-sectional views illustrating a lithography process, which is an example of a process of forming an antenna pattern as shown in FIG. 3.

In FIG. 4A, a first polymer film 41, a decorative layer 42, a second polymer film 43 are sequentially stacked, and metal foil 44a is stacked on the second polymer film 43.

Gold foil, silver foil, copper foil, or aluminum foil maybe used as the type of metal foil.

In FIG. 4B, a resist layer 46 having the shape of an antenna pattern is formed at one surface of the metal foil 44a.

The resist layer 46 may be a photo resist layer that is formed of a photosensitive material.

According to a process of forming a photo resist layer having the shape of the antenna pattern, the photo resist layer may be formed at a front surface of the metal foil, and a photo mask may be formed on the photo resist layer. The photo mask may include a transparent portion corresponding to the desired antenna pattern, and other opaque portions.

When an ultraviolet ray is irradiated onto the photo resist layer covered with the photo mask, a portion of the photo resist layer that corresponds to the transparent portion of the photo mask is cured, and the other parts of the photo resist are not cured. This process is called an exposure process. When the exposure process is completed, the photo mask can be removed.

The next process is performed using a developer on the photo resist layer from which the photo mask is removed, so that the cured portion of the photo resist layer is left and the other portions of the photo resist layer are removed. This process is called a development process.

After the development process is finally completed, a photo resist layer 46 having the shape of the antenna pattern may be formed on the metal foil 44a.

In FIG. 4C, an etching process is performed on the exposed surface of the metal foil. An etchant may be used to dissolve the metal foil. After the etching process is completed, the resist layer 46 having a desired antenna pattern and the antenna pattern 44 can be deposited.

In FIG. 4D, a film type antenna obtained by removing the resist layer 46 is shown.

The film type antenna has a structure in which the first polymer film 41, the decoration film 42, the second polymer film 43, and the antenna pattern 44 are sequentially stacked.

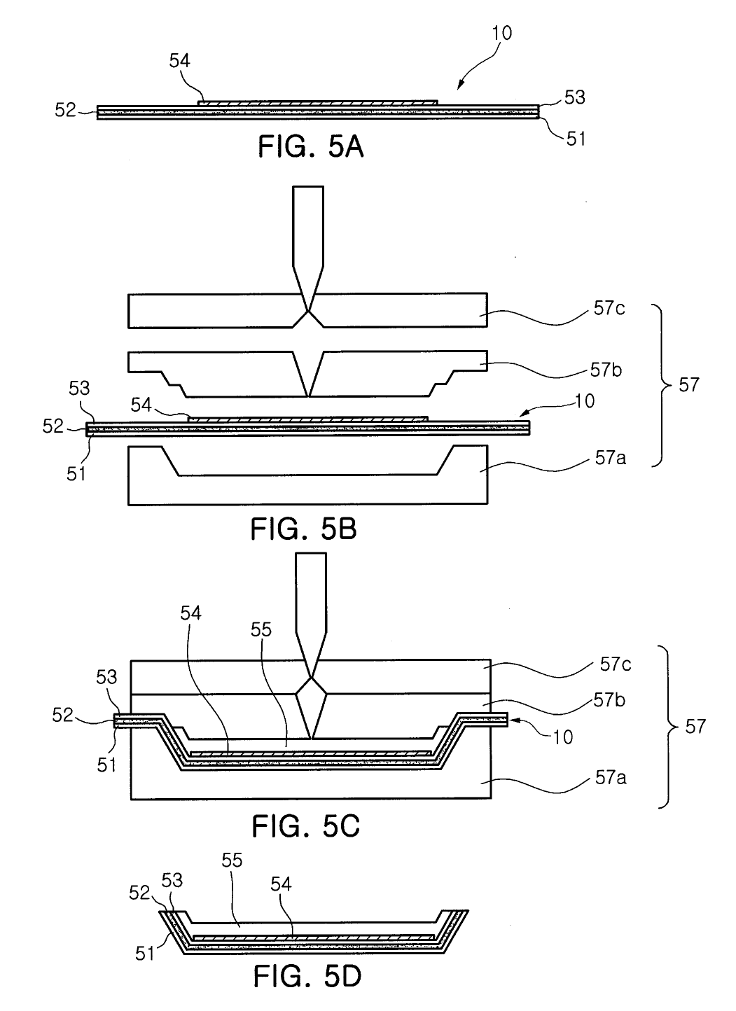

FIGS. 5A to 5D are procedural cross-sectional views illustrating a process of manufacturing a case structure according to yet another exemplary embodiment of the invention.

In FIG. 5A, the film type antenna 10 is formed.

The film type antenna 10 is formed by sequentially stacking a first polymer film 51, a decorative layer 52, a second polymer film 53, and an antenna pattern 54 are sequentially stacked. Since the first and second polymer films 51 and 53 are inserted into a mold and used during an in-mold process, the first and second polymer films 51 and 53 may be formed of a material that does not undergo significant deformation by pressure and temperature during the molding process and at the same time, can be integrally formed with a case structure.

The decorative layer 52 may be a film having a pattern printed thereon.

The antenna pattern 54 may be formed by attaching metal foil, printing a conductive ink, sputtering, or using a lithography process. The antenna pattern 54 may include a connection terminal that can be connected to an external circuit, such as a power supply terminal and a ground terminal.

In FIG. 5B, the film type antenna 10 is inserted into a mold 57. The mold 57 includes a first part 57a, a second part 57b, and a third part 57c. The first part 57 is in contact with the first polymer film 51, and forms a lower part of the mold 57. A molding material is inserted into the second part 57b, which forms an upper part of the mold 57. The third part 57c is connected to the storage of the molding material through a nozzle.

The film type antenna 10 may be inserted between the first part 57a and the second part 57b of the mold 57 such that the antenna pattern 54 formed on the second polymer film 53 is in direct contact with the surface of a housing that is formed after the molding process.

Further, the film type antenna 10 may be disposed so that the film type antenna 10 is attached to an outer surface of the housing formed after the molding process.

In FIG. 5C, all of the parts of the mold 57 are coupled and compressed.

Here, the molding material may be inserted into an area of the mold 57 under constant pressure. The pressure produces a deformation of the film type antenna 10 into the shape of the first part 57a of the mold 57. The molding material that is inserted into the mold 57 may fill a space between the first part 57a and the second part 57b of the mold 57.

In this embodiment, the film type antenna 10 is not pre-processed but is deformed by the pressure of the molding material inserted into the mold. Before the film type antenna 10 is inserted into the mold 57, a process of pre-forming the film-type antenna to the shape of the mold may be performed.

In FIG. 5D, the case structure is formed by cooling, curing, and processing the mold 57 after the compression of the mold 57.

In this embodiment, the case structure may be formed in which the film type antenna is attached to the outer surface of a housing 55. Here, the film type antenna has the first polymer film 51, the decorative layer 52, the second polymer film 53, and the antenna pattern 54 that are sequentially stacked.

As set forth above, according to the exemplary embodiments of the invention, a film type antenna having an antenna pattern and a decorative layer integrally formed with each other can be obtained, and a case structure having a housing coupled to the film type antenna can be obtained.

While the present invention has been shown and described in connection with the exemplary embodiments, it will be apparent to those skilled in the art that modifications and variations can be made without departing from the spirit and scope of the invention as defined by the appended claims.

What is claimed is:

1. A film type antenna comprising:
a first polymer film;
a decorative layer provided on one surface of the first polymer film;
a second polymer film stacked on the decorative layer and having one surface in contact with the decorative layer; and
an antenna pattern provided on the other surface of the second polymer film.

2. The film type antenna of claim 1, wherein the first and second polymer films are formed of the same material.

3. The film type antenna of claim 1, wherein the decorative layer is a film having a predetermined pattern printed thereon.

4. A case structure comprising:
a housing having at least one surface to which a film type antenna is provided,
wherein the film type antenna comprises:
a first polymer film;
a decorative layer provided on one surface of the first polymer film;
a second polymer film stacked on the decorative layer and having one surface in contact with the decorative layer; and
an antenna pattern provided on the other surface of the second polymer film.

5. The case structure of claim 4,
wherein case structure is a case of a mobile communication terminal.

6. The case structure of claim 4, wherein the film type antenna has the antenna pattern in contact with a surface of the housing.

7. The case structure of claim 4, wherein the film type antenna is provided on an outer surface of the housing.

8. A method of manufacturing a film type antenna, the method comprising:
forming a decorative layer on one surface of a first polymer film;
stacking a second polymer film so that one surface of the second polymer film is in contact with the decorative layer; and
forming an antenna pattern on the other surface of the second polymer film.

9. The method of claim 8, wherein the first polymer film and the second polymer film are formed of the same material.

10. The method of claim 8, wherein the forming a decorative layer comprises stacking a film having a predetermined pattern printed thereon on the first polymer film.

11. The method of claim 8, wherein the forming an antenna pattern comprises:
forming metal foil on the second polymer film;
forming a resist layer having the shape of an antenna on the metal foil;
etching an exposed area of the metal foil; and
removing the resist layer.

12. The method of claim 8, wherein the forming an antenna pattern comprises:
attaching a masking tape perforated in the shape of a desired antenna;
sputtering metal used to form an antenna on the surface of the second polymer film to which the masking tape is attached; and
removing the masking tape from the second polymer film.

13. The method of claim 8, wherein the forming an antenna pattern comprises:
cutting the metal foil to a desired shape; and
attaching the cut metal foil to the second polymer film.

14. A method of manufacturing a case structure, the method comprising:
forming a film type antenna in which a first polymer film, a decorative layer, a second polymer film, and an antenna pattern are sequentially stacked;
inserting the film type antenna into a mold having the shape of a case structure; and
forming a housing by inserting a molding material into the mold.

15. The method of claim 14, wherein the case structure is a case of a mobile communication terminal.

16. The method of claim 14, wherein in the inserting the film type antenna into the mold, the film type antenna is disposed so that the antenna pattern is in contact with a surface of the housing.

17. The method of claim 14, wherein in the inserting the film type antenna into a mold, the film type antenna is disposed in contact with an outer surface of the housing.

18. The method of claim 14, further comprising pre-forming the film type antenna to the shape of a desired case structure before inserting the film type antenna into the mold.
